(19) United States
(12) Patent Application Publication
(10) Pub. No.: US 2007/0278659 A1
(43) Pub. Date: Dec. 6, 2007

(54) Semiconductor package substrate and semiconductor package having the same

(75) Inventors: Wen Liang Chang, Taichung (TW); Chang Fu Chen, Taichung (TW); Yu Ting Lai, Taichung (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/732,852

(22) Filed: Apr. 4, 2007

(30) Foreign Application Priority Data
Apr. 26, 2006 (TW) 095114833

(51) Int. Cl. H01L 23/48

(52) U.S. Cl. 257/693; 257/784; 257/E23.01

(57) ABSTRACT

A semiconductor package substrate includes a substrate body and at least one intermediate bonding portion disposed on the substrate body. The substrate body includes at least one chip mounting area for mounting a chip thereon, and a plurality of electrical pads formed around the chip mounting area and for being electrically connected to the chip by bonding wires. The intermediate bonding portion is formed outside the chip mounting area of the substrate body, allowing an earlier formed free air ball to be tentatively bonded to the intermediate bonding portion before performing a wire-bonding process to bond a later formed free air ball to the chip to form a first bonding of the chip, so as to prevent detachment of the first bonding of the chip and cold-joint bonding caused by delay of the wire-bonding process. The present invention also provides a semiconductor package having the substrate.

### FIELD OF THE INVENTION

The present invention relates to semiconductor package substrates, and more particularly, to a semiconductor package substrate for packaging a chip and a semiconductor package having the substrate.

### BACKGROUND OF THE INVENTION

In view of the increasing demands for electronic products that have high functionality and miniaturized profiles and are capable of operating at high speed, it is considered necessary for a single semiconductor package to incorporate two or more semiconductor chips with the same or different functions to form a multi-chip module (MCM). Prior arts related to the MCM packages include U.S. Pat. Nos. 6,521,994, 6,617,700 and 6,798,054.

In the typical wire-bonding technology, a wire bonder is used to form a free air ball (FAB) at the tip of a capillary by a conventional computerized flame-off (EFO) apparatus, allowing the free air ball to be bonded to an input/output (I/O) connection of a chip and then connected to an electrical pad of a substrate, thereby forming a bonding wire. Therefore, a signal from the chip can be transmitted through the bonding wire, a conductive circuit, a conductive via and a ground plane (or power plane) to a solder ball disposed at a bottom surface of the substrate.

Before forming the bonding wire, however, the wire bonder must be aligned in position with the chip and thus the capillary is held in the air, making the formed free air ball become hardened due to the high temperature treatment during the EFO process. When the wire-bonding process starts to bond the firstly formed free air ball to the I/O connection of the chip to form a first bonding of the chip, the hardened free air ball cannot be well bonded to the chip, thereby leading to problems such as detachment of the first bonding of the chip and cold-joint bonding.

The problem to be solved here, therefore, is to provide a semiconductor package substrate that can successfully overcome the foregoing drawbacks in the prior art.

### SUMMARY OF THE INVENTION

In view of the above drawbacks in the prior art, an objective of the present invention is to provide a semiconductor package substrate and a semiconductor package having the substrate, so as to prevent free air balls from becoming hardened and thus avoid bonding wire detachment and cold bonding in the semiconductor package.

Another objective of the present invention is to provide a semiconductor package substrate and a semiconductor package having the substrate, so as to solve problems such as detachment of a first bonding of a chip and cold bonding in a multi-chip package.

In accordance with the above and other objectives, the present invention proposes a semiconductor package substrate comprising: a substrate body and at least one intermediate bonding portion. The substrate body comprises at least one chip mounting area for mounting a chip thereon; and a plurality of electrical pads formed around the chip mounting area, for being electrically connected to the chip by bonding wires. The intermediate bonding portion is formed outside the chip mounting area of the substrate body, allowing an earlier formed free air ball to be tentatively bonded to the intermediate bonding portion before performing a wire-bonding process to bond a later formed free air ball to the chip to form a first bonding of the chip, so as to prevent detachment of the first bonding of the chip and cold bonding which may occur due to delay of the wire-bonding process.

In the foregoing semiconductor package substrate, the substrate body can have a plurality of chip mounting areas that are spaced from each other. The intermediate bonding portion is located at a position outside each chip mounting area and close to the first bonding of the chip.

Preferably, the intermediate bonding portion is an independent bond pad formed outside the chip mounting area of the substrate body and not electrically connected to the substrate body. The plurality of electrical pads surround the corresponding chip mounting area of the substrate body. In a preferred embodiment, the substrate body is a single-chip plastic ball grid array (PBGA) substrate. In another preferred embodiment, the substrate body is a multi-chip module ball grid array (MCMBGA) substrate. In a further preferred embodiment, the substrate body is a thin and fine ball grid array (TFBGA) substrate.

The present invention also proposes a semiconductor package having the foregoing substrate. The semiconductor package comprises the substrate and an encapsulant formed on the substrate. The substrate comprises a substrate body having at least one chip mounting area for mounting a chip thereon, and at least one intermediate bonding portion formed outside the chip mounting area of the substrate body, allowing an earlier formed free air ball to be tentatively bonded to the intermediate bonding portion before performing a wire-bonding process to bond a later formed free air ball to the chip to form a first bonding of the chip, so as to prevent detachment of the first bonding of the chip and cold bonding caused by delay of the wire-bonding process. The encapsulant is used to encapsulate the chip mounted on the substrate body. The substrate further comprises a plurality of electrical pads formed around the chip mounting area, for being electrically connected to the chip by the bonding wires.

By the semiconductor package substrate and the semiconductor package having the substrate in the present invention, before forming the first bonding of the chip, an earlier formed free air ball (usually the firstly formed free air ball) can be bonded to the intermediate bonding portion, and then the wire-bonding process is performed. The intermediate bonding portion serves as a tentative bonding point where the firstly formed free air ball (which may possibly become hardened) is bonded, such that the wire-bonding process can be performed using subsequently formed free air balls (which are not hardened) to form the bonding wires, thereby avoiding bonding wire detachment and cold bonding caused by the hardened free air ball in the prior art.

### BRIEF DESCRIPTION OF THE DRAWINGS

The present invention can be more fully understood by reading the following detailed description of the preferred embodiments, with reference made to the accompanying drawings, wherein:

FIG. 1 is a schematic diagram showing a semiconductor package substrate according to a first preferred embodiment of the present invention;

FIGS. 2A, 2A′ and 2B to 2F are schematic diagrams showing steps of a bonding process performed on the semiconductor package substrate shown in FIG. 1;

FIG. 2G is a schematic diagram showing an encapsulant formed on the semiconductor package substrate shown in FIG. 1;

FIG. 3 is a schematic diagram showing a semiconductor package substrate according to a second preferred embodiment of the present invention; and

FIG. 4 is a schematic diagram showing a semiconductor package substrate according to a third preferred embodiment of the present invention.

### DETAILED DESCRIPTION OF THE PREFERRED EMBODIMENTS

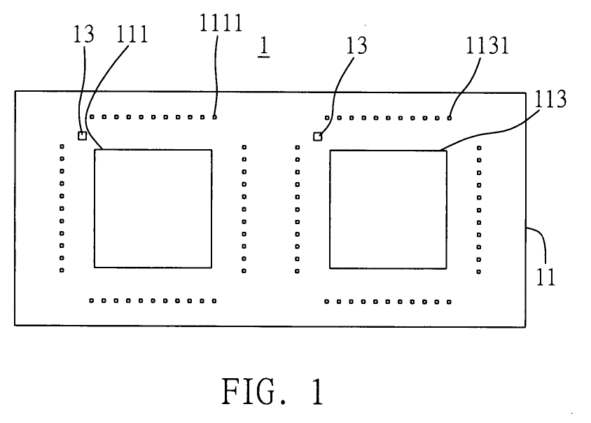

Preferred embodiments of a semiconductor package substrate and a semiconductor package having the substrate as proposed in the present invention are described as follows with reference to FIGS. 1 to 4. It should be understood that the drawings are simplified schematic diagrams only showing the elements relevant to the present invention, and the layout of elements could be more complicated in practical implementation.

### First Preferred Embodiment

Referring to FIG. 1, a semiconductor package substrate 1 according to a first preferred embodiment of the present invention comprises: a substrate body 11 and at least one intermediate bonding portion 13. The substrate body 11 comprises at least one chip mounting area; in this embodiment, two chip mounting areas 111, 113 are shown in FIG. 1 where chips can be mounted. The substrate body 11 further comprises a plurality of electrical pads 1111, 1131 respectively formed around the chip mounting areas 111, 113 and for being electrically connected to the corresponding chips by bonding wires. The intermediate bonding portion 13 is formed outside each of the chip mounting areas 111, 113 of the substrate body 11, allowing an earlier formed free air ball to be tentatively bonded to the intermediate bonding portion 13 before performing a wire-bonding process to bond a later formed free air ball to the corresponding chip to form a first bonding of the chip, so as to prevent detachment of the first bonding of the chip and cold bonding caused by the earlier formed free air ball (if become hardened) and delay of the wire-bonding process.

The substrate body 11 can be a typical single-chip plastic ball grid array (PBGA) substrate, for example, a substrate strip, in this embodiment. As the structure of the PBGA substrate is known in the art, it will not be further detailed herein.

In this embodiment, two chip mounting areas 111, 113 on the substrate body 11 are exemplified and are separated from each other. The electrical pads 1111 surround the corresponding chip mounting area 111, and the electrical pads 1131 surround the corresponding chip mounting area 113.

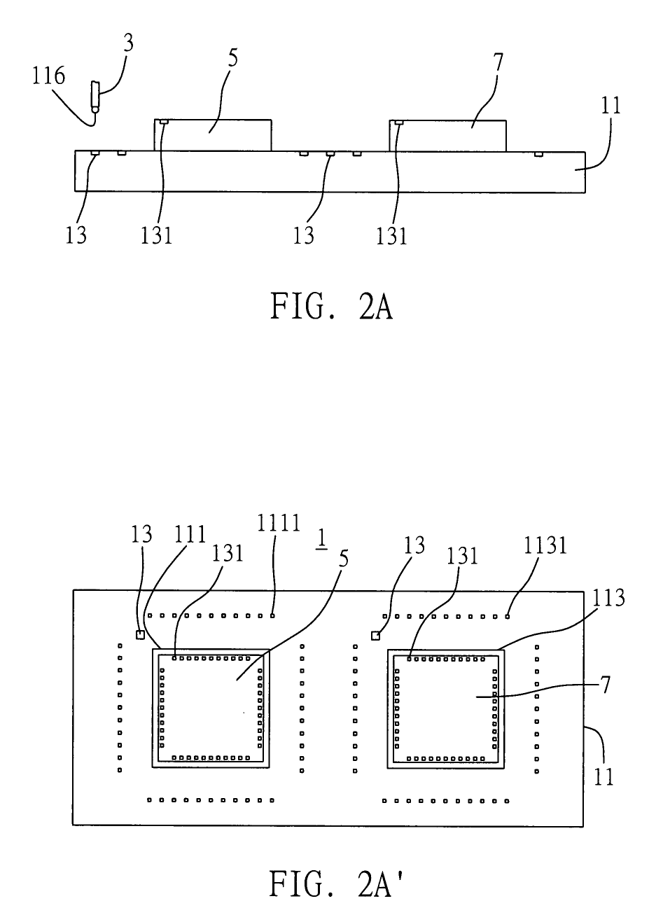

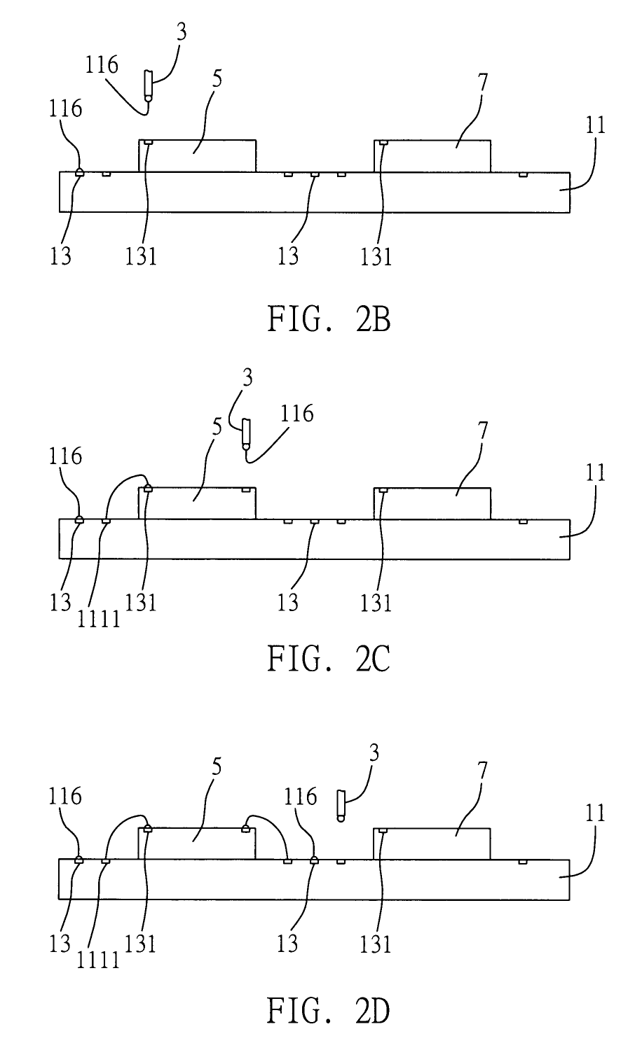

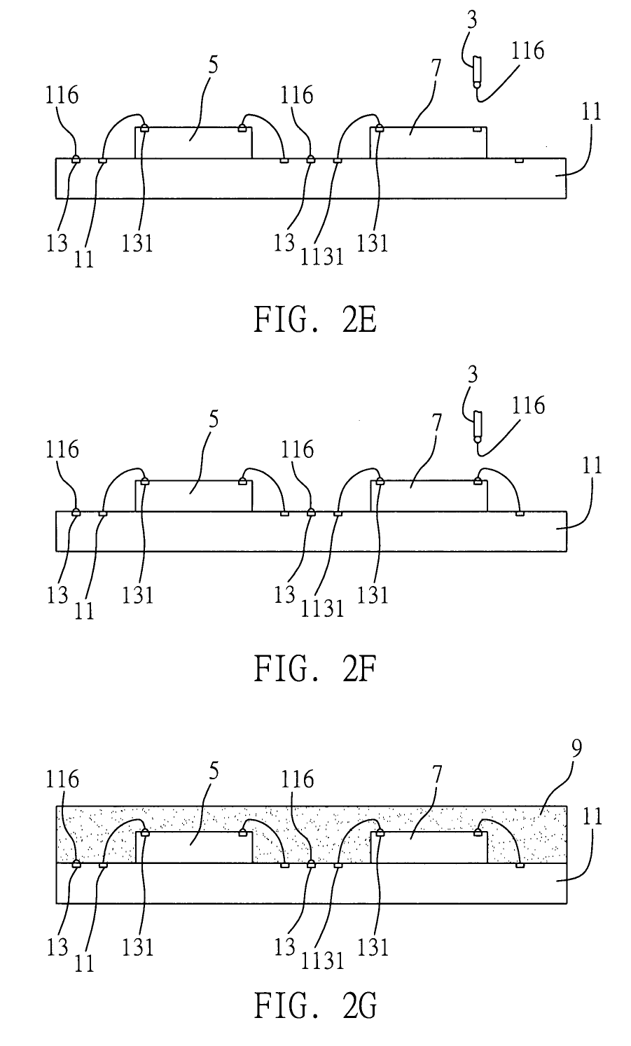

The intermediate bonding portion 13 can be located at a position outside each of the chip mounting areas 111, 113 and close to a position where the first bonding of the chip is to be formed. As shown in FIGS. 2A and 2A′, a first chip 5 and a second chip 7 are respectively attached to the chip mounting areas 111, 113 of the substrate body 11. Each of the first and second chips 5, 7 is formed with a plurality of bond pads thereon, wherein one of the bond pads of each of the chips 5, 7 is referred to as “first bond pad 131” where the first bonding is to be formed. In this embodiment, the first bond pad 131 is located at a position close to an upper left corner of each of the first and second chips 5, 7, and thus the intermediate bonding portion 13 is formed at a position close to an upper left corner of each of the chip mounting areas 111, 113 on which the first and second chips 5, 7 are mounted. For example, the intermediate bonding portion 13 is located closer the first bond pad 131 as compared with a corresponding one of the electrical pads 1111, 1131 for the first bond pad 131. The intermediate bonding portion 13 is an independent bond pad not electrically connected to the substrate body 11.

FIGS. 2A to 2F show the steps of performing a wire-bonding process on the semiconductor package substrate 1. Referring to FIG. 2A, a free air ball 116 is firstly formed by a capillary 3 of a wire bonder (not shown) before the wire-bonding process starts. Referring to FIG. 2B, the firstly formed free air ball 116 is bonded to the intermediate bonding portion 13 located outside the chip mounting area 111 and is detached from the capillary 3. Then, another free air ball 116 is formed and bonded to the first bond pad 131 of the first chip 5. The free air ball 116 is made of a bonding wire material, which is preferably, but not limited to, gold.

Referring to FIG. 2C, after the free air ball 116 is bonded to the first bond pad 131 of the first chip 5, the capillary 3 further allows the bonding wire material to be extended to a corresponding one of the electrical pads 1111 located around the chip mounting area 111 such that a bonding wire is formed to connect the first bond pad 131 of the first chip 5 to the corresponding electrical pad 1111 of the substrate body 11. The same procedures are repeated by forming subsequent free air balls 116 one by one at the tip of the capillary 3 and bonding the subsequent free air balls 116 to the other bond pads of the first chip 5 in turn until all the bond pads of the first chip 5 are electrically connected to the corresponding electrical pads 1111 of the substrate body 11 by bonding wires. After the wire-bonding process is completed for the first chip 5, the wire bonder is moved toward the second chip 7. Then, the wire-bonding process is performed on the second chip 7 in a way similar to that for the first chip 5. Referring to FIG. 2D, the wire bonder forms a free air ball 116 at the tip of the capillary 3 and bonds this free air ball 116 to the intermediate bonding portion 13 located outside the chip mounting area 113 of the substrate body 11, having this free air ball 116 detached from the capillary 3. Next, referring to FIG. 2E, another free air ball 116 is formed by the capillary 3 and is bonded to the first bond pad 131 of the second chip 7, and the capillary 3 further allows the bonding wire material to be extended to a corresponding one of the electrical pads 1131 located around the chip mounting area 113 such that a bonding wire is formed to connect the first bond pad 131 of the second chip 7 to the corresponding electrical pad 1131 of the substrate body 11. Then, referring to FIG. 2F, the same procedures are repeated by forming subsequent free air balls 116 one by one at the tip of the capillary 3 and bonding the subsequent free air balls 116 to the other bond pads of the second chip 7 in turn until all the bond pads of the second chip 7 are electrically connected to the corresponding electrical pads 1131 of the substrate body 11 by bonding wires. Finally, referring to FIG. 2G, an encapsulant 9 is formed on the to encapsulate the first and second chips 5, 7, and then a singulation process is performed to cut the encapsulant 9 and the substrate 1, thereby forming individual single-chip semiconductor packages. The singulation process is known in the art and thus is not to be further detailed herein.

In the present invention, the intermediate bonding portion is provided outside the chip mounting area of the substrate body, and serves as a tentative bonding point where the earlier formed or firstly formed free air ball (which may possibly become hardened) is bonded, such that the wire-bonding process can be performed using subsequently formed free air balls (which are not hardened) to form the bonding wires, thereby avoiding bonding wire detachment and cold bonding caused by the hardened free air ball and delay of the wire-bonding process. Therefore, the semiconductor package substrate and the semiconductor package having the substrate proposed in the present invention can desirably eliminate the drawbacks in the prior art.

### Second Preferred Embodiment

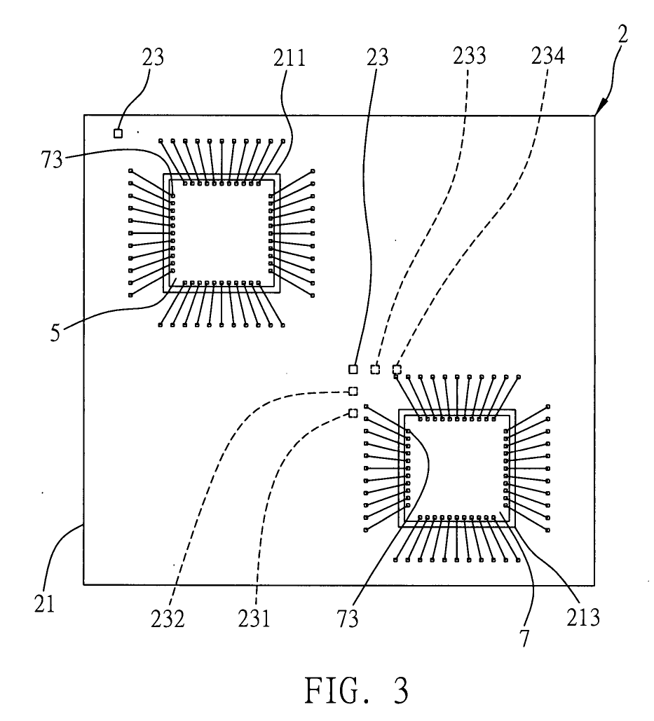

FIG. 3 is a schematic diagram showing a semiconductor package substrate and a semiconductor package having the substrate according to a second preferred embodiment of the present invention, wherein same or similar components are represented by same or similar reference numerals as compared with the first embodiment and detailed descriptions thereof are omitted to allow the present invention to be more easily understood.

The second embodiment primarily differs from the first embodiment in that, the second embodiment illustrates a multi-chip module ball grid array (MCMBGA) package, wherein the intermediate bonding portion is formed outside the chip mounting area of the substrate body, and is located at a position close to the first bond pad of the chip but farther from the first bond pad as compared with the corresponding electrical pad for the first bond pad.

Referring to FIG. 3, a semiconductor package 2 comprises a substrate body 21 having chip mounting areas 211, 213 for mounting chips 5, 7 thereon respectively, and at least one intermediate bonding portions 23 formed outside each of the chip mounting areas 211, 213 and at a position close to a corner corresponding to the location of a first bond pad 73 of each of the chips 5, 7. In this embodiment, the substrate body 21 is a MCMBGA substrate and the semiconductor package 2 is a MCMBGA package.

Before performing a wire-bonding process on the substrate body 21, the chips 5, 7 are respectively attached to the chip mounting areas 211, 213. A capillary of a wire bonder (not shown) is used to bond a firstly formed free air ball to the intermediate bonding portion 23 located around the chip mounting area 211, and then the wire-bonding process is performed using subsequently formed free air balls to form bonding wires for electrically connecting the chip 5 to the substrate body 21. After the wire-bonding process is completed for the chip 5, the wire bonder is moved toward the chip 7. Similarly, the capillary of the wire bonder forms a free air ball and bond this free air ball to the intermediate bonding portion 23 located around the chip mounting area 213, and then the wire-bonding process is performed using subsequently formed free air balls to form bonding wires for electrically connecting the chip 7 to the substrate body 21.

The location of the intermediate bonding portion is not limited to that close to the corner of each of the chip mounting areas, but can alternatively be close to one of edges forming the corner. For example, as shown in FIG. 3, the intermediate bonding portion can alternatively be formed at locations 231, 232, 233 and/or 234 (only the case for the chip mounting area 213 is shown) as long as the intermediate bonding portion is close to the first bond pad 73 of the corresponding chip.

As discussed above, by providing the intermediate bonding portion located outside the chip mounting area of the substrate body, a tentative free air ball can be bonded to the intermediate bonding portion before performing the wire-bonding process on the chip, such that bonding wire detachment or cold bonding caused by the hardened free air ball in the prior art can be avoided.

### Third Preferred Embodiment

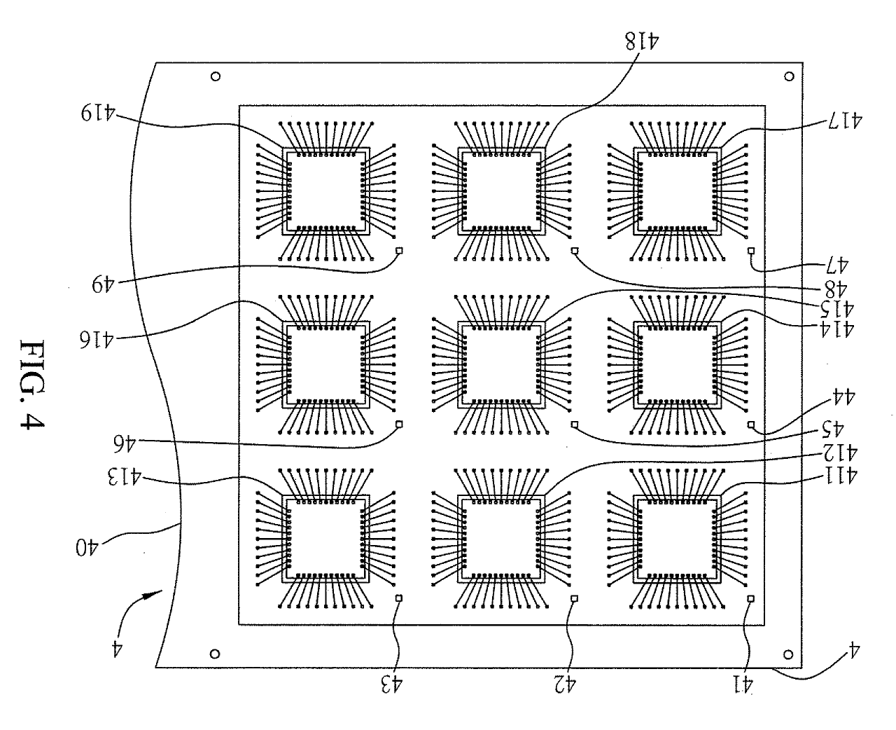

FIG. 4 is a schematic diagram showing a semiconductor package substrate and a semiconductor package having the substrate according to a third preferred embodiment of the present invention, wherein same or similar components are represented by same or similar reference numerals as compared with the first embodiment and detailed descriptions thereof are omitted to allow the present invention to be more easily understood.

The third embodiment primarily differs from the second embodiment in that, the third preferred embodiment illustrates a thin and fine ball grid array (TFBGA) package.

Referring to FIG. 4, a semiconductor package 4 comprises a substrate body 40 having chip mounting areas 411 to 419 for mounting chips 51 to 59 thereon respectively, and intermediate bonding portions 41 to 49 each of which is formed outside a corresponding one of the chip mounting areas 411 to 419 and at a position close to a first bond pad of a corresponding one of the chips 51 to 59. In this embodiment, the substrate body 40 is a TFBGA substrate and the semiconductor package 4 is a TFBGA package.

As discussed above, by providing the intermediate bonding portion located outside each of the chip mounting areas of the substrate body, the foregoing wire-bonding process can be performed repeatedly on the chips in turn, thereby preventing bonding wire detachment or cold bonding which may occur due to delay of the wire-bonding process. Furthermore, the present invention is flexibly applicable to various types of substrates and different numbers of chip packages, thereby having design flexibility and high industrial applicability.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor package substrate comprising:
a substrate body comprising at least one chip mounting area for mounting a chip thereon, and a plurality of electrical pads formed around the chip mounting area and for being electrically connected to the chip by bonding wires; and
at least one intermediate bonding portion formed outside the chip mounting area of the substrate body, allowing an earlier formed free air ball to be tentatively bonded to the intermediate bonding portion before performing a wire-bonding process to bond a later formed free air ball to the chip to form a first bonding of the chip, so as to prevent detachment of the first bonding of the chip and cold-joint bonding in the wire-bonding process.

2. The semiconductor package substrate of claim 1, wherein the substrate body comprises a plurality of chip mounting areas separated from each other.

3. The semiconductor package substrate of claim 1, wherein the intermediate bonding portion is located at a position close to a first bond pad of the chip where the first bonding is formed.

4. The semiconductor package substrate of claim 1, wherein the free air ball is made of a bonding wire material.

5. The semiconductor package substrate of claim 4, wherein the bonding wire material is gold.

6. The semiconductor package substrate of claim 1, wherein the intermediate bonding portion is an independent bond pad free of being lectrically connected to the substrate body.

7. The semiconductor package substrate of claim 1, wherein the plurality of electrical pads surround the chip mounting area.

8. The semiconductor package substrate of claim 1, wherein the substrate body is one of a single-chip plastic ball grid array (PBGA) substrate, a multi-chip module ball grid array (MCMBGA) substrate, and a thin and fine ball grid array (TFBGA) substrate.

9. A semiconductor package comprising
a substrate comprising a substrate body having at least one chip mounting area for mounting a chip thereon, and at least one intermediate bonding portion formed outside the chip mounting area of the substrate body, allowing an earlier formed free air ball to be tentatively bonded to the intermediate bonding portion before performing a wire-bonding process to bond a later formed free air ball to the chip to form a first bonding of the chip, so as to prevent detachment of the first bonding of the chip and cold-joint bonding in the wire-bonding process; and
an encapsulant formed on the substrate and encapsulating the chip.

10. The semiconductor package of claim 9, wherein the substrate further comprises a plurality of electrical pads formed around the chip mounting area, for being electrically connected to the chip by bonding wires.

11. The semiconductor package of claim 10, wherein the electrical pads surround the chip mounting area.

12. The semiconductor package of claim 9, wherein the substrate body comprises a plurality of chip mounting areas separated from each other.

13. The semiconductor package of claim 9, wherein the intermediate bonding portion is located at a position close to a first bond pad of the chip where the first bonding is formed.

14. The semiconductor package of claim 9, wherein the free air ball is made of a bonding wire material.

15. The semiconductor package of claim 14, wherein the bonding wire material is gold.

16. The semiconductor package of claim 9, wherein the intermediate bonding portion is an independent bond pad free of being electrically connected to the substrate body.

17. The semiconductor package of claim 9, wherein the substrate body is one of a single-chip plastic ball grid array (PBGA) substrate, a multi-chip module ball grid array (MCMBGA) substrate, and a thin and fine ball grid array (TFBGA) substrate.
